(19) United States
(12) Patent Application Publication
(10) Pub. No.: US 2018/0368271 A1
(43) Pub. Date: Dec. 20, 2018

(54) Device and Method for Producing a Device With a Printed Circuit Board Which is Arranged Within a Housing and Which Can Be Contacted From the Outside

(71) Applicant: Robert Bosch GmbH, Stuttgart (DE)

(72) Inventors: Oliver Schilli, Lichtenstein (DE); Reinhold Jocham, Hechingen (DE); Ulrich Trescher, Tuebingen (DE)

(21) Appl. No.: 15/775,994

(22) PCT Filed: Nov. 3, 2016
(86) PCT No.: PCT/EP2016/076556

§ 371 Date: May 14, 2018

(30) Foreign Application Priority Data
Dec. 4, 2015 (DE) 10 2015 224 354.0

(51) Int. Cl. H05K 5/00; H05K 5/02

(52) U.S. Cl. CPC H05K 5/0069; H05K 5/0247

(57) ABSTRACT

A device includes a housing, a printed circuit board, and a connection element. The housing includes a plug collar having an opening from an exterior of the housing to an interior of the housing. The printed circuit board is arranged in the housing. The connection element partly receives at least one plug pin and is fixed to the housing, such that the plug pin is arranged partly within the plug collar and partly on the interior of the housing. The connection element is arranged partly within the plug collar and partly on the interior of the housing, and the plug pin is electrically contacted directly to the printed circuit board.

### PRIOR ART

The invention proceeds from an apparatus having a housing, which has a connector collar having an opening from an outer side to an inner side of the housing, and having a connection element, which partially holds at least one connector pin, wherein the connection element is fixed on the housing in such a way that the connector pin is arranged partially inside the connector collar and partially on the inner side of the housing.

An apparatus of this kind is disclosed, for example, in the laid-open specification DE 10300767 A1, wherein in this case the connection element is mounted with the connector pin into the opening of the connector collar from the outside.

Alternatively, it is known to arrange a connector pin in a housing cover by means of injection molding. It is also known that, during the mounting of the housing cover, the connector pin is then connected to a printed circuit board by way of an adapter. The connection between the connector pin and the adapter is established here, for example, by means of insulation displacement technology.

### DISCLOSURE OF THE INVENTION

The invention proceeds from an apparatus having a housing, which has a connector collar having an opening from an outer side to an inner side of the housing, and having a connection element, which partially holds at least one connector pin, wherein the connection element is fixed on the housing in such a way that the connector pin is arranged partially inside the connector collar and partially on the inner side of the housing.

The core of the invention consists in the connection element being arranged partially inside the connector collar and partially on the inner side of the housing and in the connector pin being electrically contact-connected directly to a printed circuit board arranged in the housing.

What is advantageous here is that the connection element is mounted on the inner side of the housing. This creates the option of connecting the connection element to the connector pin and then the connector pin directly to the printed circuit board during production of the apparatus and this before all of it is enclosed by the housing, as a result of which an otherwise necessary adapter can be omitted. By dispensing with the adapter, there is also more space in the main extension plane of the printed circuit board and the lateral extent of the printed circuit board can be reduced. In addition, by minimizing the number of contact-connection interfaces from the connector input up to the printed circuit board, the susceptibility of the apparatus to faults is reduced. Furthermore, by dispensing with the adapter, the number of components is reduced, as a result of which production costs and outlay can be reduced. In the case of a plurality of connector pins, a small pitch can also be achieved.

An advantageous refinement of the invention makes provision for the connector pin to be of bent or else angled design in at least one region between the connection element and the printed circuit board. What is advantageous here is that the bending or else the angling of the connector pin effects a tolerance compensation between the printed circuit board and the connection element, as a result of which forces acting on the connection element due to a connector are transmitted as little as possible to the contact-connection interface between the printed circuit board and the connector pin. As a result thereof, said contact-connection interface undergoes less strain and has a longer lifetime.

A further advantageous refinement of the invention makes provision for the connector pin to have a first cross-sectional area in at least one region between the connection element and the printed circuit board, said first cross-sectional area being reduced with respect to a second cross-sectional area of a part of the connector pin held by the connection element.

What is advantageous here is that the reduced cross section of the connector pin in the region between the connection element and the printed circuit board improves the tolerance compensation and can reduce the forces acting on the contact-connection interface between the connector pin and the printed circuit board.

In accordance with an advantageous refinement of the invention, there is provision for the connection element to have a grip element.

What is advantageous here is that the connection element can be accessed as easily as possible by means of the grip element.

In accordance with a further advantageous refinement of the invention, there is provision for the grip element to have at least one predetermined breaking point for separating the grip element from the connection element. What is advantageous here is that the grip element can be separated from the connection element by means of the predetermined breaking point as soon as the grip element is no longer required.

In an advantageous embodiment of the invention, there is provision for the connection element to have a protrusion, which bears against the housing on the inner side of the housing and projects beyond the opening of the connector collar.

What is advantageous here is that the protrusion serves as a stop for the connection element with respect to the housing and the connection element can therefore be inserted into the opening of the connector collar to only a limited extent.

In a further advantageous embodiment of the invention, there is provision for the connection element to be fixed on the housing by means of laser welding, in particular laser spot welding, wherein the housing is designed to be at least partially able to be welded through by laser beams in a subregion in which the connection element bears against the housing.

What is advantageous here is that the connection element is firmly connected to the housing. As a result thereof, the connection element can also be welded on from the outer side of the housing.

An advantageous embodiment of the invention makes provision for a first width of the connection element, which is arranged inside the connector collar, to be equal to a second width of the opening of the connector collar.

What is advantageous here is that the connection element is therefore firmly arranged in the direction of the width with respect to the connector collar and no offset can occur. The position of the connector pin in the connector collar can therefore be prescribed.

The invention also relates to a method for producing an apparatus having a housing, which has a connector collar having an opening from an outer side to an inner side of the housing, having a connection element, having a printed circuit board and having at least one connector pin, having at least the following method steps:
a. inserting and fixing a part (48) of the connector pin in the connection element,
b. directly electrically contact-connecting the connector pin to the printed circuit board,
c. arranging the printed circuit board and the connection element with the connector pin in the housing,
d. inserting a part of the connection element into the opening of the connector collar from the direction of the inner side of the housing in such a way that the connector pin is arranged partially inside the connector collar and partially on the inner side of the housing,
e. fixing the connection element on the housing.

What is advantageous here is that the connector pin can be arranged precisely in position on the printed circuit board. Furthermore, the connection element is mounted on the inner side of the housing. This creates the option of connecting the connection element to the connector pin and then the connector pin directly to the printed circuit board during production of the apparatus and this before all of it is arranged in the housing, as a result of which an otherwise necessary adapter can be omitted. By dispensing with the adapter, there is also more space in the main extension plane of the printed circuit board and the lateral extent of the printed circuit board can be reduced. In addition, by minimizing the number of contact-connection interfaces from the connector input up to the printed circuit board, the susceptibility of the apparatus to faults is reduced. Furthermore, by dispensing with the adapter, the number of components is reduced, as a result of which production costs and outlay can be reduced. In the case of a plurality of connector pins, a small pitch can also be achieved.

In an advantageous refinement of the method according to the invention, there is provision for a method step f in which the connector pin is bent and/or angled to proceed before method step c.

What is advantageous here is that the bending or else the angling of the connector pin effects a tolerance compensation between the printed circuit board and the connection element, as a result of which forces acting on the connection element due to a connector are transmitted as little as possible to the contact-connection interface between the printed circuit board and the connector pin. As a result thereof, said contact-connection interface undergoes less strain and has a longer lifetime.

In accordance with an advantageous refinement of the method according to the invention, there is provision for the connection element to be fixed in method step e by means of laser beam welding.

What is advantageous here is that the connection element is firmly fixed to the housing and the fixing from the outer side of the housing is made possible.

In accordance with a further advantageous refinement of the method according to the invention, there is provision, in method step d, for the connection element to be inserted into the opening of the connector collar by means of pulling on a grip element of the connection element from the direction of the inner side of the housing.

What is advantageous here is that the connection element can be accessed as easily as possible by the grip element in order to insert it into the connector collar.

In an advantageous refinement of the method according to the invention, there is provision, in a method step g, which is carried out after method step e, for the grip element to be separated from the connection element by means of a predetermined breaking point of the grip element.

What is advantageous here is that, after the connection element has been fixed on the housing, the grip element can be separated by means of the predetermined breaking point since it is then no longer required and, for example, during a later contact-connection of the connector pin, is therefore no longer in the way from the outside.

In a further advantageous refinement of the method according to the invention, there is provision for the connector pin to be inserted into and fixed in the connection element in method step a by means of pressing-in and/or by means of injection molding.

What is advantageous here is that the press fit or else the injection molding technology represent simple options for integrating a part of the connector pin into the connection element.

In a further advantageous refinement of the method according to the invention, there is provision for the connector pin to be electrically contact-connected to the printed circuit board in method step b by means of pressing-in or else by means of material bonding.

What is advantageous here is that the press fit or else the material bonding technology represent simple options for electrically contact-connecting the connector pin to the printed circuit board.

### DRAWINGS

FIG. 1a to FIG. 1f show an exemplary embodiment of an apparatus according to the invention in different steps of the production method.

FIG. 2 shows an exemplary embodiment of a production method according to the invention.

### DESCRIPTION OF EXEMPLARY EMBODIMENTS

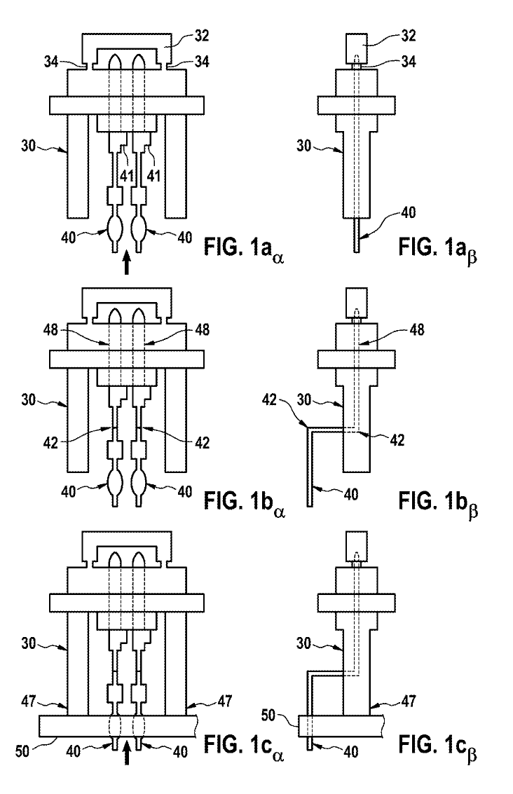

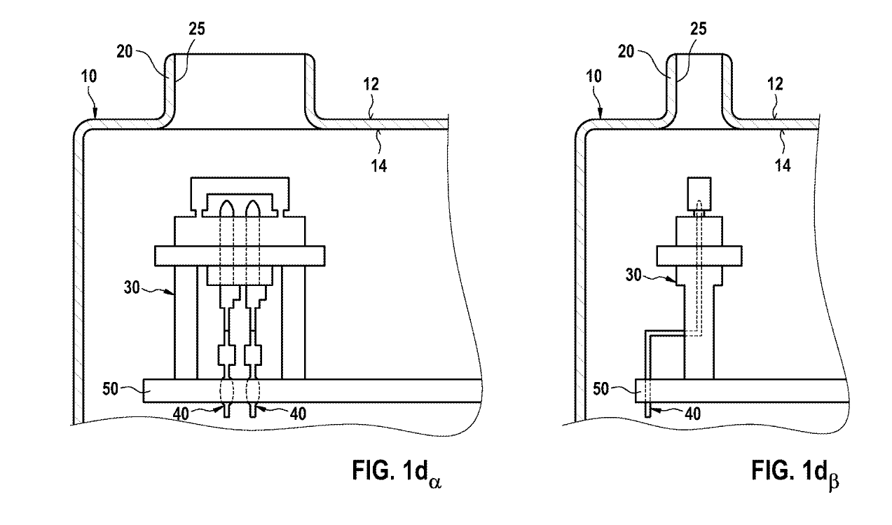

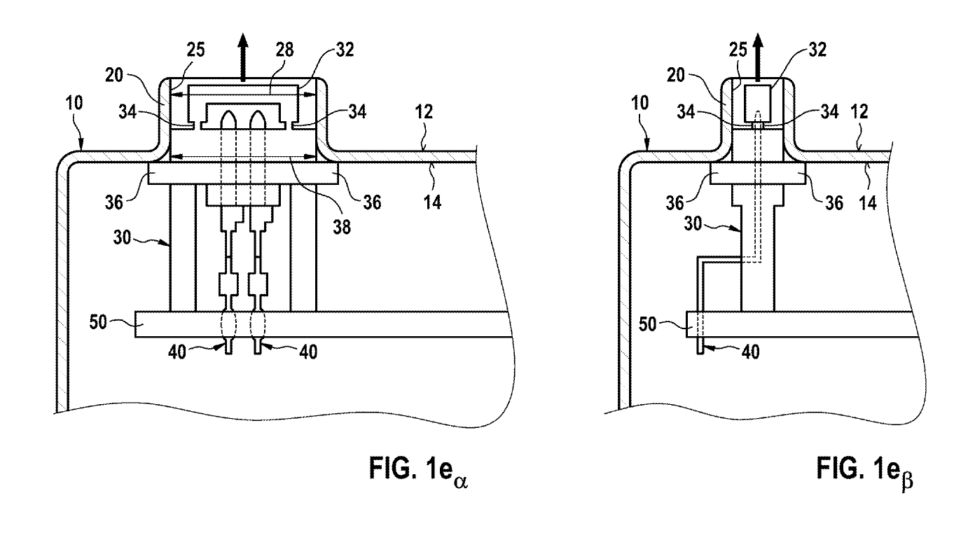

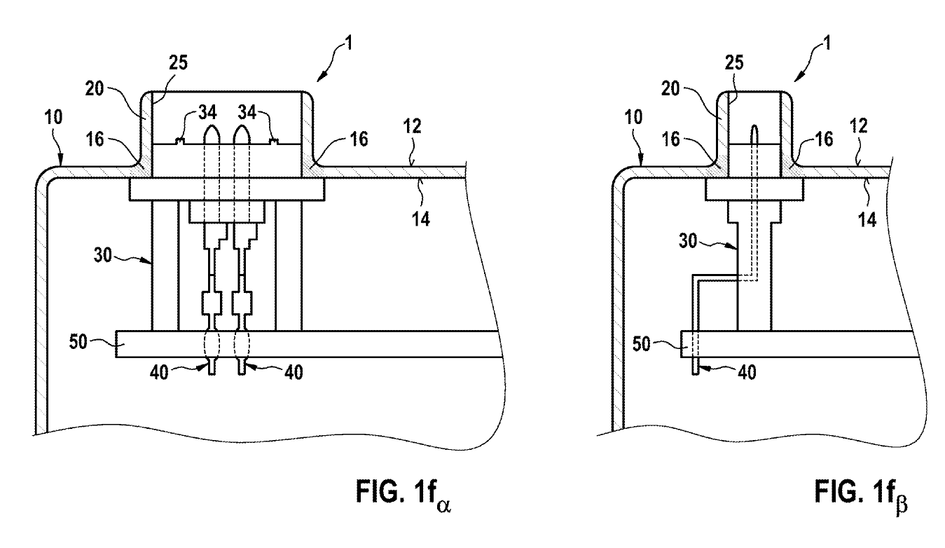

FIG. 1a to FIG. 1f show an exemplary embodiment of an apparatus according to the invention according to different steps of the production method, wherein the finished apparatus can be a control device, for example.

In this case, the figures denoted with the subscript α show a first side view and the figures denoted with the subscript β show a second side view. The first side view is in each case illustrated in a manner offset to the second side view by an angle of 90°.

FIG. 1a_{α} and FIG. 1a_{β} show a connection element 30 into which two connector pins 40 are partially inserted. The connector pins 40 have been inserted into the connection element 30 from the direction of the illustrated arrow in such a way that the connector pins 40 emerge again on the opposite side to the insertion. Furthermore, the connector pins 40 have projecting elements 41, which limit the insertion depth of the connector pins 40 into the connection element 30. The connection element 30 has a grip element 32, which in this case is configured as a bracket, for example. The grip element 32 furthermore has two predetermined breaking points 34, which serve for the separation of the grip element 32 from the connection element 30. In an alternative exemplary embodiment (not illustrated), the grip element 32 can also be configured in a different way, for example as a simple rod, and possibly then requires only one predetermined breaking point 34 for separating the grip element 32 from the connection element 30.

FIG. 1b_{α} and FIG. 1b_{β} again show the connection element 30. However, the connector pins 40 inserted into the connection element 30 from FIG. 1a_{α} and FIG. 1a_{β} are not of angled design in a region 42. Furthermore, the connector pins 40 in this region 42 have a first cross-sectional area, which is configured to be reduced with respect to a second cross-sectional area of a part 48 of the connector pins 40 held by the connection element 40. In an alternative exemplary embodiment not illustrated in the figures, the connector pins 40 in the region 42 are bent or else bent and angled, by virtue of, for example, bending following angling, instead of just being of angled design.

FIG. 1c_{α} and FIG. 1c_{β} show the connection element 30, wherein the connector pins 40 inserted into the connection element 30 are electrically contact-connected directly to a printed circuit board 50. The connector pins 40 are electrically connected to the printed circuit board 50 by means of a press fit. In this case, the printed circuit board 50 has been placed onto the connector pins 40 from the direction of the arrow, wherein the connection element 30 has two stop elements 47, which prevents a further placement of the printed circuit board 50 onto the connector pins 40 and also stabilizes the connector pins 40 with respect to the printed circuit board 50.

FIG. 1d_{α} and FIG. 1d_{β} show the intermediate product from FIG. 1c_{α} and FIG. 1c_{β}, which is arranged in a housing 10. The housing 10 has a connector collar 20. The connector collar 20 again has an opening 25 from an inner side 14 of the housing 10 to an outer side 12 of the housing 10. FIG. 1e_{α} and FIG. 1e_{β} illustrate the connection element 30 from FIG. 1d_{α} and FIG. 1d_{β}, which is connected to the printed circuit board 50 by means of the connector pins 40. Here, the connection element 30 is arranged partially in the opening 25 of the connector collar 20 and partially on the inner side 14 of the housing 10 and has been inserted into the opening 25 in the direction of the arrow from the inner side 14 of the housing 10. Here, the connection element 30 has a protrusion 36, which bears against the housing 10 on the inner side 14 of the housing 10 and projects beyond the opening 25 of the connector collar 20 in such a way that the connection element 30 cannot be inserted any further into the opening 25. Furthermore, the connection element 30 has a first width 38, which is equal to a second width 28 of the opening 25 of the connector collar 20. As a result thereof, the position of the connection element 30 in the opening 25 is prescribed at least in a first direction. It is also conceivable for the connection element 30 to have a third width, which is equal to a fourth width of the connector collar 20, in order to prescribe the position of the connection element 30 in the connector collar 20 in a second direction as well, wherein the first and second direction are preferably oriented vertically parallel to the opening surface of the connector collar 20 and also vertically with respect to one another.

FIG. 1f_{α} and FIG. 1f_{β} show the connection element 30 inserted into the opening 25 of the connector collar 20 according to FIG. 1e_{α} and FIG. 1e_{β}. Here, the connection element 30 is welded on the housing 10 at least at points and is therefore attached in a stationary manner with respect to the housing 10. Here, the protrusion 36 of the connection element 30 is preferably welded to the housing 10. To make laser beam welding from the outer side 12 of the housing 10 possible, the housing 10 has a subregion 16 against which the connection element 30 bears from the inner side 14 of the housing 10 and which able to be welded through by laser beams. Furthermore, the grip element 32 of the connection element 30 illustrated in the preceding FIG. 1a_{α}, and FIG. 1a_{β} to FIG. 1e_{α}, and FIG. 1e_{β} is removed at the predetermined breaking point 34 and therefore creates the finished apparatus 1.

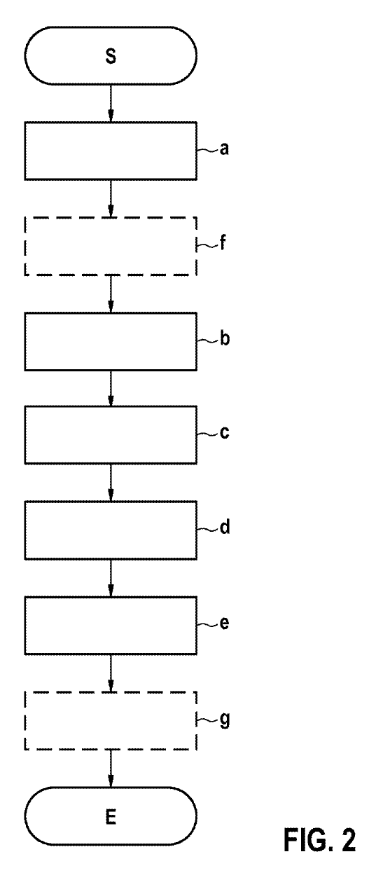

FIG. 2 shows a first exemplary embodiment of a production method according to the invention. First, in a method step a, at least one part 48 of a connector pin 40 is inserted into and fixed in a connection element 30. This is effected here by means of pressing-in, by virtue of the connector pin 40 being pressed through the connection element 40 from one direction. Here, the connector pin 40 then protrudes again from the connection element 40 on opposite sides thereof. This therefore produces, for example, an intermediate product according to FIG. 1a_{α} and FIG. 1a_{β}. Then, in a method step b, the connector pin 40 is electrically contact-connected directly to a printed circuit board 50. The electrical contact-connection is likewise effected here, for example, by means of pressing-in, by virtue of the connector pin 40 being pressed vertical to a main extension plane of the printed circuit board 50 into a receptacle in the printed circuit board 50 provided for this purpose. As a result thereof, for example, an intermediate product according to FIG. 1c_{α} and FIG. 1c_{β} is therefore produced. Subsequently, in a method step c, the printed circuit board 50 and the connection element 30 connected to the printed circuit board 50 by means of the connector pin 40 is arranged in a housing 10 having a connector collar 20, wherein the connector collar 20 has an opening 25 from an inner side 14 of the housing 10 to an outer side 12 of the housing 10. Such an intermediate product is shown by way of example in FIG. 1d_{α} and FIG. 1d_{β}. The arrangement in the housing 10 can be effected, for example, by virtue of the housing 10 having a housing cover and a housing base. During mounting of the housing cover onto the housing base, the connection element 30 is then arranged with the conductor pin 40 and the printed circuit board 40 inside the housing 10. Then, in a method step d, the connection element 30 is inserted partially into the opening 25. This takes places in this case from the direction of the inner side 14 of the housing 10 in such a way that the connector pin 40 is arranged partially inside the connector collar 20 and partially on the inner side 14 of the housing 10. The insertion is effected until a protrusion 36 of the connection element 30 bears against the housing 10 on the inner side 14. Such an intermediate product is illustrated by way of example in FIG. 1e_{α} and FIG. 1e_{β}. To insert the connection element 30 into the opening 25, a possibly present grip element 32 of the connection element 30 can be used here, by virtue of the grip element 32 of the connection element 30 arranged on the inner side 14 of the housing 10 being accessed from the outer side 12 through the opening 25 and then the connection element 30 being pulled partially into the opening 25 by means of pulling on the grip element 32. In a following method step e, the connection element 30 is fixed on the housing 10. The connection element 30 is fixed in method step f, for example, by means of laser beam welding, in particular from the outer side 12 of the housing 10 and, in particular, by virtue of the protrusion 36 of the connection element 30 being welded on the housing 10 at least at points.

The production method optionally has another method step f, which proceeds before method step b. In method step f, the connector pin 40 is bent or else angled in at least one region 42, wherein care should be taken to ensure that the region 42 is located between the printed circuit board 40 and the connection element 30 in the later method step c. Such an intermediate product is illustrated by way of example in FIG. 1b_{α} and FIG. 1b_{β}. Alternatively, method step f can also take place before method step a or between method step b and c.

A method step g is also optionally carried out provided that the connection element 30 has a grip element 32 having a predetermined breaking point 32. In this method step g, the grip element 32 is separated from the connection element 30 by means of the predetermined breaking point 34.

In an alternative exemplary embodiment of the production method not illustrated in the figures, in method step a, the connector pin 40 is inserted into and fixed in the connection element 30 by means of injection molding. In a further alternative exemplary embodiment not illustrated in the figures, in method step b, the electrical contact-connection is effected by means of material bonding, for example by means of soldering or welding.

1. An apparatus, comprising:
a housing including a connector collar having an opening from an outer side to an inner side of the housing;
a printed circuit board arranged in the housing; and
a connection element partially holding at least one connector pin and fixed on the housing, such that the at least one connector pin is arranged partially inside the connector collar and partially on the inner side of the housing,
wherein the connection element is arranged partially inside the connector collar and partially on the inner side of the housing, and
wherein the connector pin is electrically contact-connected directly to the printed circuit board.

2. The apparatus as claimed in claim 1, wherein the at least one connector pin is bent and/or angled in at least one region between the connection element and the printed circuit board.

3. The apparatus as claimed in claim 1, wherein:
the at least one connector pin has a first cross-sectional area in at least one region between the connection element and the printed circuit board, and
the first cross-sectional area is reduced with respect to a second cross-sectional area of a part of the at least one connector pin held by the connection element.

4. The apparatus as claimed in claim 1, wherein the connection element includes a grip element.

5. The apparatus as claimed in claim 4, wherein the grip element includes at least one predetermined breaking point configured to separate the grip element from the connection element.

6. The apparatus as claimed in claim 1, wherein the connection element includes a protrusion configured to bear against the housing on the inner side of the housing and projecting beyond the opening of the connector collar.

7. The apparatus as claimed in claim 1, wherein:
the connection element is fixed on the housing via laser welding; and
the housing is configured to be at least partially welded through by laser beams in a subregion in which the connection element bears against the housing.

8. The apparatus as claimed in claim 1, wherein a first width of the connection element arranged inside the connector collar is equal to a second width of the opening of the connector collar.

9. A method for producing an apparatus including a housing having a connector collar with an opening from an outer side to an inner side of the housing, a connection element, a printed circuit board, and at least one connector pin, the method comprising:
inserting and fixing at least one part of the at least one connector pin in the connection element;
directly electrically contact-connecting the at least one connector pin to the printed circuit board;
arranging the printed circuit board and the connection element with the at least one connector pin in the housing;
inserting a part of the connection element into the opening of the connector collar from a direction of the inner side of the housing, such that the at least one connector pin is arranged partially inside the connector collar and partially on the inner side of the housing; and
fixing the connection element on the housing.

10. The method as claimed in claim 9, further comprising:
bending and/or angling the at least one connector pin before arranging the printed circuit board and the connection element with the at least one connector pin in the housing.

11. The method as claimed in claim 9, further comprising:
fixing the connection element on the housing via laser beam welding.

12. The method as claimed in claim 9, wherein inserting the part of the connection element into the opening of the connector collar comprises:
pulling on a grip element of the connection element from the direction of the inner side of the housing.

13. The method as claimed in claim 12, further comprising:
separating the grip element from the connection element via a predetermined breaking point of the grip element after fixing the connection element on the housing.

14. The method as claimed in claim 9, wherein inserting and fixing the at least one part of the at least one connector pin in the connection element includes pressing-in and/or injection molding.

15. The method as claimed in claim 9, wherein directly electrically contact-connecting the at least one connector pin to the printed circuit board includes pressing-in and/or material bonding.

16. The apparatus as claimed in claim 7, wherein the connection element is fixed on the housing via laser spot welding.
